(19) United States
(12) Patent Application Publication
(10) Pub. No.: US 2026/0096217 A1
(43) Pub. Date: Apr. 2, 2026

(54) IC DEVICE, LAYOUT, AND METHOD

(71) Applicant: TAIWAN SEMICONDUCTOR MANUFACTURING COMPANY, LTD., Hsinchu (TW)

(72) Inventors: Kuan Yu CHEN, Hsinchu (TW); Chun-Yen LIN, Hsinchu (TW); Wei-Cheng LIN, Hsinchu (TW); Jiann-Tyng TZENG, Hsinchu (TW)

(21) Appl. No.: 19/013,520

(22) Filed: Jan. 8, 2025

Related U.S. Application Data
(60) Provisional application No. 63/701,207, filed on Sep. 30, 2024.

(51) Int. Cl. H10D 89/10; G06F 30/392; H01L 23/522; H01L 23/528; H10D 84/01; H10D 84/85

(52) U.S. Cl. CPC H10D 89/10; G06F 30/392; H10D 84/0165; H10D 84/85; H10W 20/42; H10W 20/427

(57) ABSTRACT

An IC device includes isolation structures extending between two locations along a first direction in a front side of a semiconductor substrate, transistors including gates and MD segments extending between the two locations and being entireties of gates and MD segments positioned between the two locations and between the isolation structures in a second direction perpendicular to the first direction, frontside gate vias being an entirety of frontside gate vias electrically connected to the gates, and frontside S/D vias being an entirety of frontside S/D vias electrically connected to the MD segments. All of the frontside gate vias are positioned at locations of first and/or second tracks of first through third layer tracks extending in the second direction and being an entirety of lowermost frontside metal layer tracks positioned between the two locations, and all of the frontside S/D vias are positioned at locations of the second and/or third tracks.

### PRIORITY CLAIM

The present application claims the priority of U.S. Provisional Application No. 63/701,207, filed Sep. 30, 2024, which is incorporated herein by reference in its entirety.

### BACKGROUND

The ongoing trend in miniaturizing integrated circuits (ICs) has resulted in progressively smaller devices which consume less power, yet provide more functionality at higher speeds than earlier technologies. Such miniaturization has been achieved through design and manufacturing innovations tied to increasingly strict specifications. Various electronic design automation (EDA) tools are used to generate, revise, and verify designs for semiconductor devices while ensuring that IC structure design and manufacturing specifications are met.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are plan views and a cross-sectional view of an IC device and layout diagram, in accordance with some embodiments.

FIGS. 2A-2C are a schematic diagram and plan views of an IC device and layout diagram, in accordance with some embodiments.

FIG. 3 is a flowchart of a method of manufacturing an IC device, in accordance with some embodiments.

FIG. 4 is a flowchart of a method of generating an IC layout diagram, in accordance with some embodiments.

FIG. 5 is a block diagram of an IC layout diagram generation system, in accordance with some embodiments.

FIG. 6 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, an integrated circuit (IC) device, layout diagram, and manufacturing method are directed to transistors including gates and metal-like defined (MD) segments arranged between isolation structures in an area corresponding to a cell including a total of three lowermost frontside metal layer tracks. An entirety of frontside gate vias are positioned along the first and second tracks and an entirety of frontside source/drain (S/D) vias are positioned along the second and third tracks. The transistor arrangement, e.g., a logic circuit, is thereby capable of being positioned adjacent to a second transistor arrangement, e.g., an electrically equivalent circuit, such that each gate and S/D via of the first arrangement is separated from each gate and S/D via of the second arrangement by at least one track.

The separation distance is thereby sufficiently large to allow an entirety of the gate and S/D vias of the transistor arrangements to be included in a single mask, e.g., an extreme ultraviolet (EUV) mask, and to allow cut poly and cut MD regions to conform to minimum spacing process limits. The IC device is thereby capable of being manufactured using a single mask such that production costs and complexity are reduced compared to other approaches, e.g., those that include multiple masks.

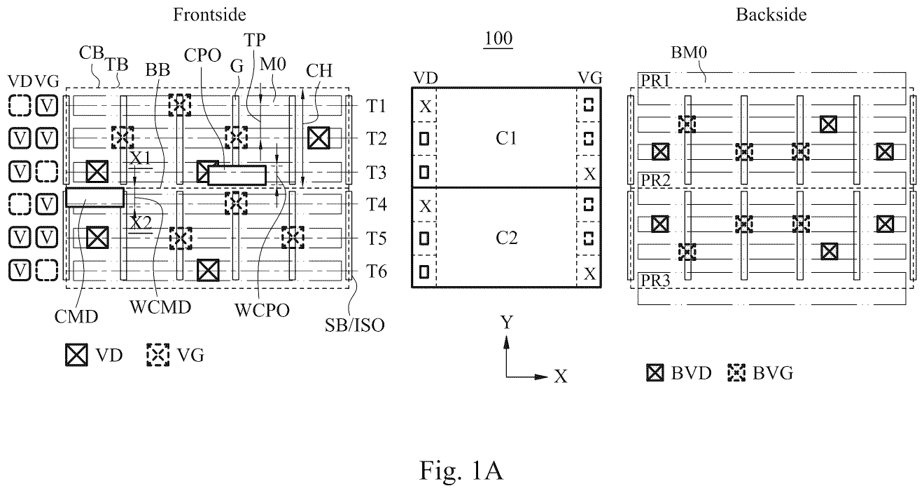

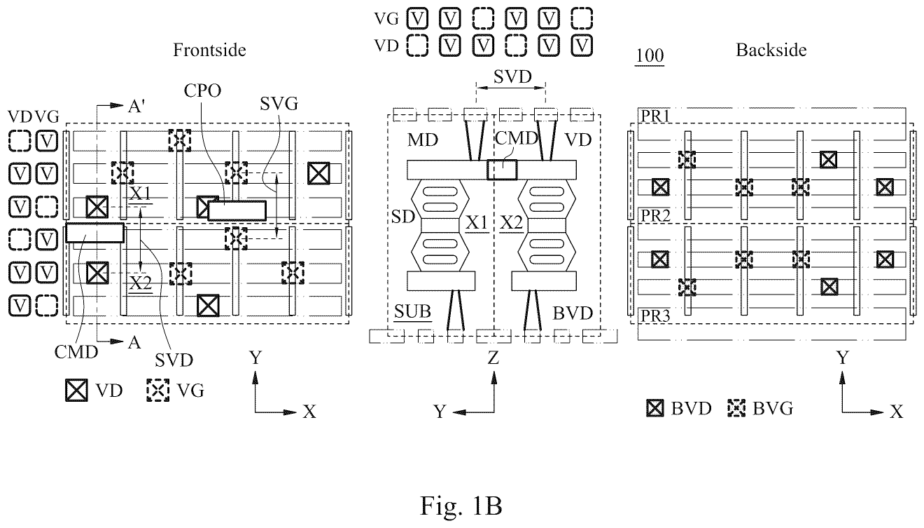

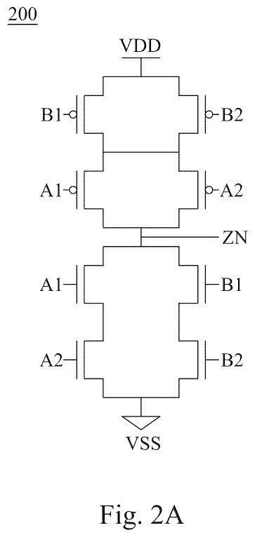

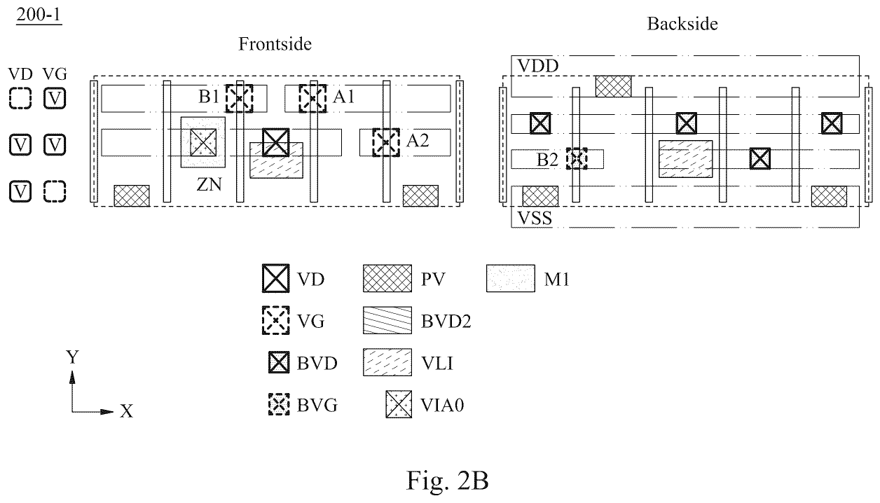

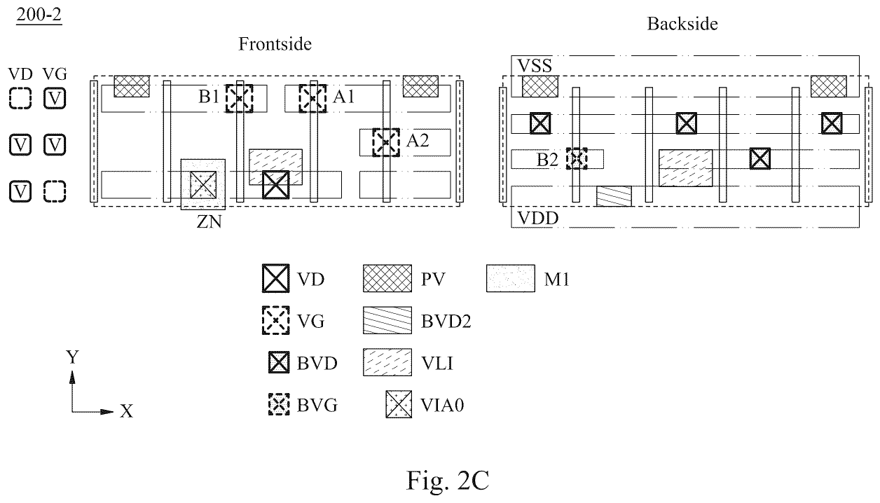

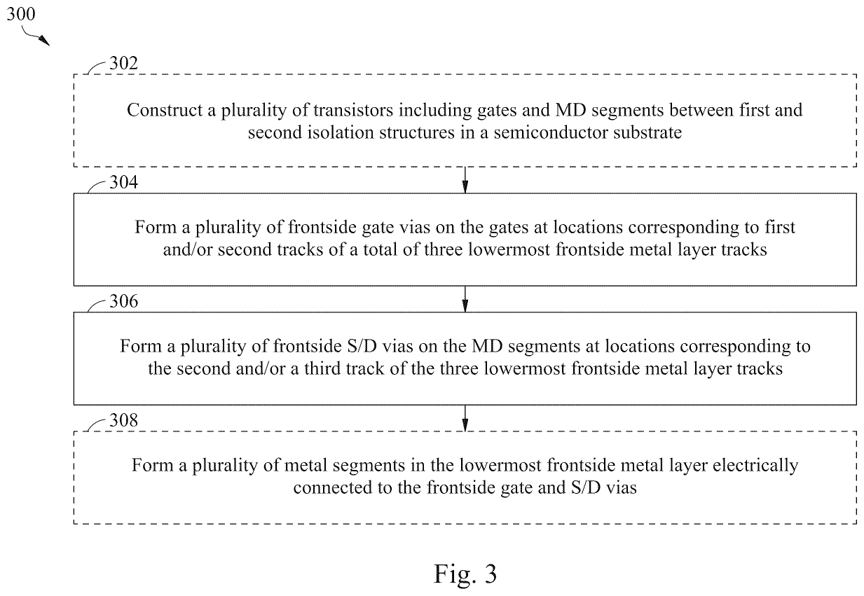

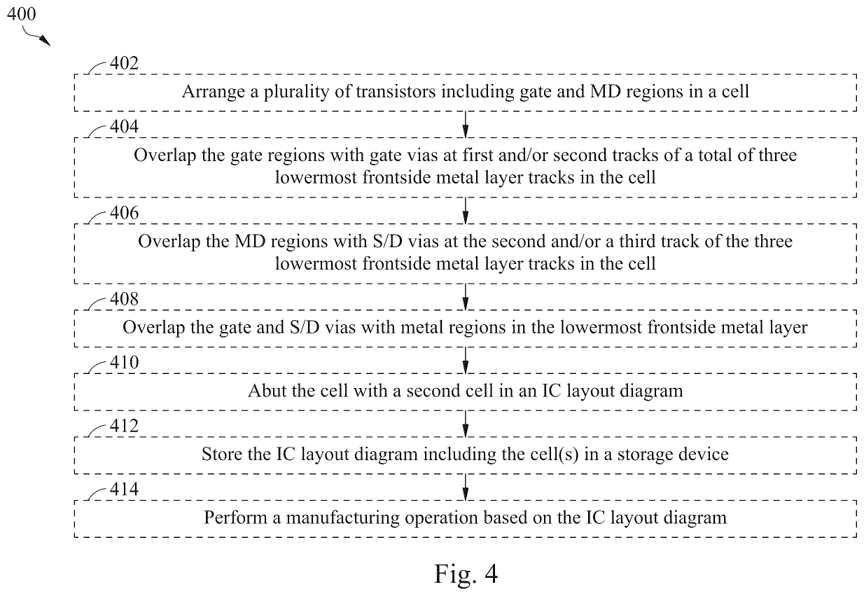

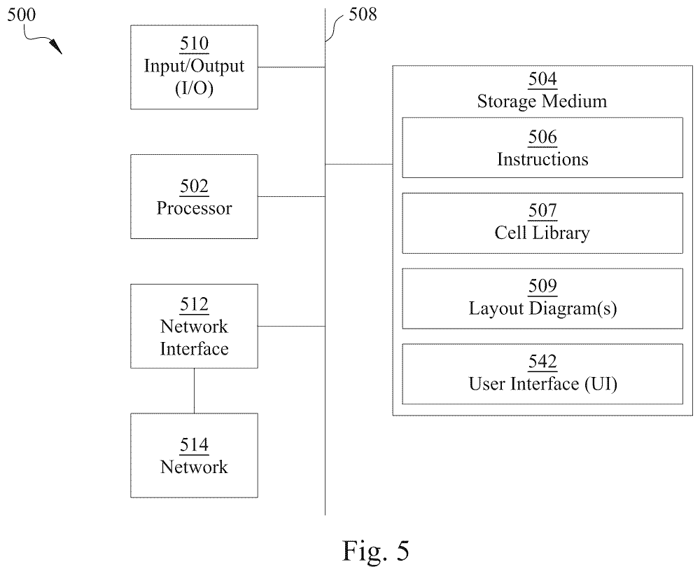

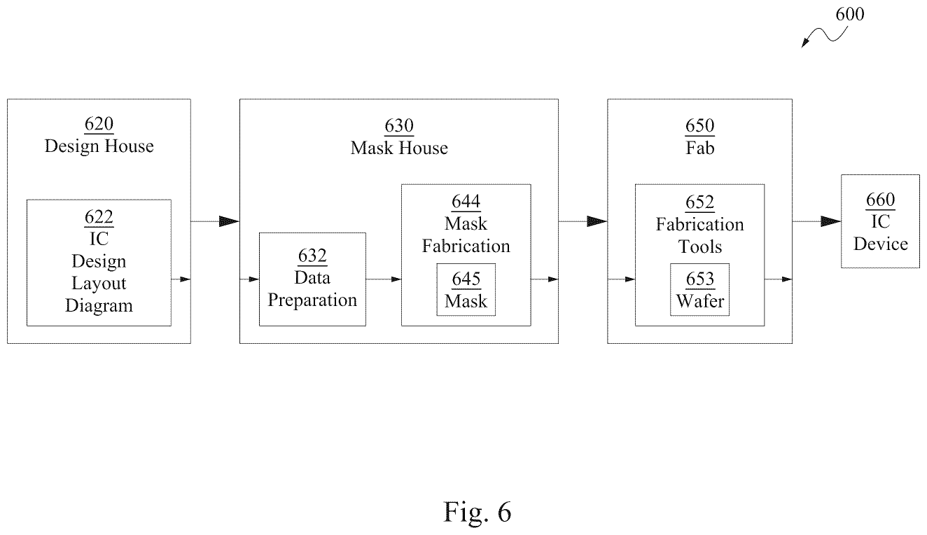

As discussed below, in accordance with various embodiments, FIGS. 1A and 1B are plan views and a cross-sectional view of an IC device and layout diagram 100, FIGS. 2A-2C are a schematic diagram 200 and plan views of IC devices and layout diagrams 200-1 and 200-2, FIG. 3 is a flowchart of a method 300 of manufacturing a memory circuit, and FIG. 4 is a flowchart of a method 400 of generating an IC layout diagram, e.g., using an IC layout diagram generation system 500 depicted in FIG. 5 and/or in accordance with an IC manufacturing flow 600 depicted in FIG. 6.

Each of the figures herein, e.g., FIGS. 1A, 1B, 2B, and 2C, is simplified for the purpose of illustration. The figures are views of IC structures, devices, and layout diagrams with various features included and excluded to facilitate the discussion below. In various embodiments, an IC structure, device and/or layout diagram includes one or more features corresponding to power distribution structures, metal interconnects, contacts, vias, gate structures, S/D structures, bulk connections, or other transistor elements, isolation structures, or the like, in addition to the features depicted in FIGS. . 1A, 1B, 2B, and 2C.

In each of IC devices/layout diagrams 100, 200-1, and 200-2, reference designators represent both IC device features and the IC layout features used to at least partially define the corresponding IC device features in a manufacturing process, e.g., method 300 discussed below with respect to FIG. 3 and/or the IC manufacturing flow associated with IC manufacturing system 600 discussed below with respect to FIG. 6. Accordingly, each of IC devices/layout diagrams 100, 200-1, and 200-2 represents a view of both an IC layout diagram 100, 200-1, or 200-2 and a corresponding IC device 100, 200-1, or 200-2.

Each of IC layout diagrams/devices 100, 200-1, and 200-2 and IC layout diagrams/structures 100, 200-1, and 200-2 discussed below includes arrangements of some or all of at least one of a semiconductor substrate, an active region/area, a S/D region/structure, an MD region/segment, a gate region/structure, a metal region/segment, a via region/structure, and/or an isolation region/structure, each discussed below.

A semiconductor substrate, e.g., a substrate SUB, is a portion, e.g., a die, or all of a semiconductor wafer, e.g., a silicon (Si) wafer, or an epitaxial Si layer, suitable for forming one or more IC devices, e.g., IC devices 100, 200-1, and 200-2. In each of the embodiments discussed below, a semiconductor substrate includes a front side within which a first subset of the features of the IC devices are formed through a first set of manufacturing processes, e.g., front-end-of-line (FEOL) processes, middle-end-of-line (MEOL) processes, and back-end-of-line (BEOL) processes, and a back side within which a second subset of the features of the IC devices are formed through a second set of manufacturing processes, e.g., backside metallization processes, performed after the first set of manufacturing processes are performed.

An active region/area is a region in an IC layout diagram included in a manufacturing process as part of defining an active area, also referred to as an oxide diffusion or definition (OD), in the semiconductor substrate, either directly or in an n-well or p-well region/area, in which one or more IC device features, e.g., a S/D structure, is formed. In some embodiments, an active area is an n-type or p-type active area of a planar transistor, a fin field-effect transistor (FinFET), a gate-all-around (GAA) transistor, a complementary field-effect transistor (CFET), or another transistor configuration including a gate region/structure.

In various embodiments, an active area (structure) includes one or more of a semiconductor material, e.g., silicon (Si), silicon-germanium (SiGe), silicon-carbide (SiC), or the like, a dopant material, e.g., boron (B), aluminum (Al), phosphorous (P), arsenic (As), gallium (Ga), or another suitable material.

In some embodiments, an active area is a region in an IC layout diagram included in the manufacturing process as part of defining a nano-sheet structure, e.g., a continuous volume of one or more layers of one or more semiconductor materials having either n-type or p-type doping. In various embodiments, individual nano-sheet layers include a single monolayer or multiple monolayers of a given semiconductor material.

A S/D region/structure, e.g., S/D region/structure SD, is a region in the IC layout diagram included in the manufacturing process as part of defining a S/D structure, also referred to as a semiconductor structure in some embodiments, configured to have a doping type opposite that of the corresponding active region/area. In some embodiments, a S/D region/structure is configured to have lower resistivity than an adjacent channel feature, e.g., a portion of the corresponding active region/area of a planar FET or CFET, a fin structure of a FinFET, or a gate structure of a GAA transistor. In some embodiments, a S/D region/structure includes one or more portions having doping concentrations greater than one or more doping concentrations present in the corresponding channel feature. In some embodiments, a S/D region/structure includes one or more epitaxial regions of a semiconductor material, e.g., Si, SiGe, and/or silicon-carbide SiC. A S/D region/structure, also referred to as a S/D terminal in some embodiments, may refer to a source or a drain, individually or collectively, dependent upon the context.

An MD region/segment, e.g., MD region/segment MD, is a conductive region in the IC layout diagram included in the manufacturing process as part of defining an MD segment, also referred to as a conductive segment or MD conductive line or trace, in and/or on the semiconductor substrate. In some embodiments, an MD region overlaps an active area at a location of a S/D region in the IC layout diagram, and the corresponding MD segment contacts and is electrically connected to the S/D structure of the active area.

In some embodiments, an MD segment includes a portion of at least one metal layer, e.g., a contact layer, overlying and contacting the substrate and having a thickness sufficiently small to enable formation of an insulation layer between the MD segment and an overlying metal layer, e.g., the first metal layer. In various embodiments, an MD segment includes one or more of copper (Cu), silver (Ag), tungsten (W), titanium (Ti), nickel (Ni), tin (Sn), aluminum (Al) or another metal or material suitable for providing a low resistance electrical connection between IC structure elements, i.e., a resistance level below a predetermined threshold corresponding to one or more tolerance levels of a resistance-based effect on circuit performance.

In various embodiments, an MD segment includes a section of the semiconductor substrate and/or an epitaxial layer having a doping level, e.g., based on an implantation process, sufficient to cause the segment to have the low resistance level. In various embodiments, a doped MD segment includes one or more dopant materials having doping concentrations of about 1*1016 per cubic centimeter (cm-3) or greater.

In some embodiments, a manufacturing process includes two MD layers, and an MD region/segment, e.g., MD region/segment MD, refers to both of the two MD layers in the manufacturing process. In some embodiments, an MD segment is configured to be electrically connected to the S/D structure of a single one of a p-type or n-type FET of a CFET, and to be electrically isolated from the S/D structure of the other of the p-type or n-type FET of the CFET. In some embodiments, an MD segment, also referred to as an MD local interconnect (MDLI), local interconnect (LI), or vertical local interconnect (VLI) in some embodiments, is configured to be electrically connected to the S/D structures of both the p-type FET and the n-type FET of a CFET.

A cut-MD region, e.g., a cut-MD region CMD, is a region in the IC layout diagram included in the manufacturing process as part of defining a discontinuity in a given MD structure, e.g., a portion etched away after the MD structure has been formed, thereby resulting in adjacent and aligned MD segments electrically isolated from each other.

A gate region/structure, e.g., a gate region/structure G, also referred to as a gate G in some embodiments, is a region in the IC layout diagram included in the manufacturing process as part of defining a gate structure. A gate structure is a volume including one or more conductive segments, e.g., a gate electrode, including one or more conductive materials, e.g., polysilicon, copper (Cu), aluminum (Al), tungsten (W), cobalt (Co), ruthenium (Ru), or one or more other metals or other suitable materials, substantially surrounded by one or more insulating materials, the one or more conductive segments thereby being configured to control a voltage provided at an adjacent gate dielectric layer.

A gate dielectric layer, e.g., a gate dielectric layer of a gate structure G, is a volume including one or more insulating materials, e.g., silicon dioxide, silicon nitride (Si₃N₄), and/or one or more other suitable material such as a low-k material having a k value less than 3.8 or a high-k material having a k value greater than 3.8 or 7.0 such as aluminum oxide (Al2O₃), hafnium oxide (HfO₂), tantalum pentoxide (Ta₂O₅), or titanium oxide (TiO₂), suitable for providing a high electrical resistance between IC structure elements, i.e., a resistance level above a predetermined threshold corresponding to one or more tolerance levels of a resistance-based effect on circuit performance.

In some embodiments, a gate region/structure corresponds to a dummy gate region/structure, e.g., an isolation region/structure ISO. In some embodiments, a dummy gate region/structure includes a gate electrode electrically connected, e.g., tied-off, to one or more features, e.g., a power rail or other metal segment or an adjacent instance of a S/D region/structure such that a transistor corresponding to the dummy gate region/structure and overlapping/underlying active region/area is switched off by design. In some embodiments, a dummy gate region/structure that overlaps/overlies an edge of an active region/area is referred to as a continuous poly on oxide definition edge (CPODE) region/structure.

In some embodiments, an isolation region/structure, e.g., isolation region/structure ISO, includes a gate dielectric layer and/or one or more other dielectric layers and is thereby configured as an insulation layer capable of electrically isolating adjacent S/D structures, MD segments, or other conductive features from each other.

A cut-gate region, e.g., a cut-gate region CPO, also referred to as a cut-poly region in some embodiments, is a region in the IC layout diagram included in the manufacturing process as part of defining a discontinuity in a given gate structure, e.g., a portion etched away after the gate electrode has been formed, thereby resulting in adjacent and aligned gate electrode segments electrically isolated from each other.

A metal line or region, e.g., a frontside metal region/segment M0 or M1, a backside metal region/segment BM0, or power rail PR1-PR3, VDD, or VSS, is a region in the IC layout diagram included in the manufacturing process as part of defining a metal line, or segment, including one or more conductive materials, e.g., polysilicon, copper (Cu), aluminum (Al), tungsten (W), cobalt (Co), ruthenium (Ru), or one or more other metals or other suitable materials, in a given frontside or backside metal layer of the manufacturing process.

In some embodiments, a metal region/segment, e.g., metal region/segment M0, corresponds to a first, or lowermost, frontside metal layer (also referred to as a metal zero layer or frontside metal zero layer in some embodiments), or a second or higher level frontside metal layer of the manufacturing process. In some embodiments, a second frontside metal layer is referred to as a metal one layer or frontside metal one layer and a second frontside metal region/segment, e.g., metal region/segment M1, is referred to as a metal one region/segment.

In some embodiments, a backside metal region/segment, e.g., metal region/segment BM0, corresponds to a first, or lowermost, backside metal layer (also referred to as a backside metal zero layer in some embodiments), or a second or higher level backside metal layer of the manufacturing process.

In some embodiments, a metal region/segment, e.g., power rail PR1-PR3, VDD, or VSS, corresponds to a component of a power distribution network configured to distribute one or both of a power supply voltage, e.g., a power supply voltage VDD, and a reference or ground voltage, e.g., reference voltage VSS. The power distribution network component is electrically connected to one or more features, e.g., additional metal regions/segments and/or via regions/structures, configured to distribute the corresponding power supply or reference voltage and be electrically isolated from IC components outside the distribution network.

A via region/structure, e.g., a via region/structure VG, VD, VIA0, BVD, BVG, BVD2, or PV, also referred to as a via in some embodiments, is a region in the IC layout diagram included in the manufacturing process as part of defining a via structure including one or more conductive materials configured to provide an electrical connection between a first, e.g., overlying, conductive structure, e.g., a metal segment M0 or M1, backside metal segment BM0, or power rail PR1-PR3, VDD, or VSS, and a second, e.g., underlying, conductive structure, e.g., a metal segment, a gate electrode of a gate structure G, an instance of MD segment MD, or a S/D structure, aligned with the first conductive structure in the Z direction.

In some embodiments, a via region/structure VG and/or backside via region/structure BVG corresponds to the underlying conductive structure being the gate electrode of a gate region/structure G, and/or a via region/structure VD and/or backside via region/structure BVD corresponds to the underlying conductive structure being a S/D region/structure or MD region/segment MD.

FIGS. 1A and 2A include plan views of IC layout diagram/device 100 and include a cross-sectional view along line A-A′ of FIG. 2A and X, Y, and Z directions. FIG. 2A is a schematic diagram of an AND-OR-INVERT circuit 200 and FIGS. 2B and 2C are plan views of respective electrically equivalent IC layout diagrams/devices 200-1 and 200-2 and include the X and Y directions. In some cases, for the purpose of clarity, not all instances of each feature included IC layout diagrams/devices 100, 200-1, and 200-2 are labeled in FIGS. 1A, 1B, 2B, and 2C.

IC layout diagrams/devices 100, 200-1, and 200-2 correspond to CFETs having nanosheet configurations for the purpose of illustration. IC layout diagrams/devices including the configurations discussed below corresponding to other transistor types, e.g., FinFETs or planar transistors, are within the scope of the present disclosure.

As depicted in FIGS. 1A and 1B, IC layout diagram/device 100 includes cells C1 and C2 adjacent to each other along the Y direction. In addition to frontside and backside features of IC layout diagram/device 100 depicted in each of FIGS. 1A and 1B, FIG. 1A includes a block diagram of cells C1 and C2, and FIG. 1B includes a cross-sectional view of cells C1 and C2.

A cell, e.g., cell C1 or C2, is some or all of an IC layout diagram including features arranged in accordance with one or more electrical functions, e.g., a logic function, of an IC device manufactured based on the IC layout diagram.

Each of cells C1 and C2 has a cell border CB including a top border TB extending in the X direction, bottom border BB extending in the X direction, and side borders SB extending in the Y direction. A distance between top border TB and bottom border BB corresponds to a cell height CH.

Cell C1 shares bottom border BB with top border TB of cell C2, the combined border extending in the X direction and being referred to as a shared border of cells C1 and C2 in some embodiments.

Side borders SB correspond to instances of isolation region/structure ISO that extend in the Y direction between first and second locations corresponding to top border TB and bottom border BB. Thus, an IC device corresponding to cell C1 or C2 can be considered to be positioned between the corresponding instances of isolation structure ISO in both the X and Y directions.

In the embodiment depicted in FIGS. 1A and 1B, side borders SB of cells C1 and C2 are aligned in the Y direction such that cells C1 and C2 and the resultant IC devices extend between isolation regions/structures ISO at same locations along the X direction. In some embodiments, one or both of the side borders of cell C1 do not align with a corresponding side border SB of cell C2 such that cells C1 and C2 and the resultant IC devices extend between isolation regions/structures ISO at differing locations along the X direction.

Cells C1 and C2 include respective pluralities of transistors X1 and X2, each including some or all of a gate G extending in the Y direction, S/D regions/structures SD adjacent to the corresponding gate G in each of the positive and negative X directions, and MD regions/segments MD overlying the S/D regions/structures SD in each of the positive and negative Z directions.

In the non-limiting example depicted in FIGS. 1A and 1B, cells C1 and C2 include a total of four CFET transistors X1 or X2. Other numbers and types of transistors X1 and X2 are within the scope of the present disclosure.

Each of transistors X1 of cell C1 and transistors X2 of cell C2 are configured to, in operation, perform one or more logic or other electrical functions. In some embodiments, e.g., IC layout diagrams/devices 200-1 and 200-2 discussed below, cells C1 and C2 are electrically equivalent cells in which transistors X1 and X2 are configured non-identically to perform a same electrical function. In some embodiments, transistors X1 and X2 are configured non-identically to perform differing electrical functions.

Some or all of the instances of gates G and MD regions/segments MD in cell C1 are aligned in the Y direction with some or all of the instances of gates G and MD regions/segments MD in cell C2. At some or all of the locations along the shared border at which gates G and MD regions/segments MD are aligned, cells C1 and/or C2 include respective cut-gate regions CPO and cut-MD regions CMD configured to electrically isolate the corresponding gates G and MD segments in the IC devices corresponding to cells C1 and C2 from each other. A given cut-gate region CPO has a width WCPO in the Y direction corresponding to a separation distance between adjacent aligned gates G, and a given cut-MD region has a width WCMD in the Y direction corresponding to a separation distance between adjacent aligned MD segments MD.

Tracks T1-T6 extend across cells C1 and C2 in the X direction such that a total of three tracks T1-T3 extend across cell C1 and a total of three tracks T4-T6 extend across cell C2. Tracks T1-T6 define allowable locations of metal regions/segments M0 in a lowermost frontside metal layer of IC layout diagram/device 100, e.g., by defining center lines of metal regions/segments M0 extending in the X direction, and are referred to as lowermost frontside metal layer tracks T1-T6 in some embodiments.

Tracks T1-T6 are spaced apart in the Y direction by a pitch TP. In some embodiments, cell height CH is equal to three times pitch TP. In some embodiments, track T2 is centered in cell C1 along cell height CH and track T5 is centered in cell C2 along cell height CH.

IC layout diagram/device 100 includes a power rail PR1 extending in the X direction in a lowermost backside metal layer at a Y direction location corresponding to top border TB of cell C1, a power rail PR2 extending in the X direction in the lowermost backside metal layer at a Y direction location corresponding to the shared border of cells C1 and C2, and a power rail PR3 extending in the X direction in the lowermost backside metal layer at a Y direction location corresponding to bottom border TB of cell C2.

Each of power rails PR1 and PR3 is included in a power distribution network configured to have one of a power supply voltage or a reference voltage, and power rail PR2 is included in a power distribution network configured to have the other of the power supply voltage or the reference voltage.

In the embodiment depicted in FIGS. 1A and 1B, IC layout diagram/device 100 includes a total of two metal regions/segments BM0 extending in the X direction in the lowermost backside metal layer between power rails PR1 and PR2 and between power rails PR2 and PR3. In some embodiments, IC layout diagram/device 100 includes zero, a single metal region/segment BM0, or more than two metal regions/segments BM0 extending in the X direction in the lowermost backside metal layer between power rails PR1 and PR2 and/or between power rails PR2 and PR3.

FIGS. 1A-2C depict each of metal regions/segments M0 and BM0 extending in the X direction, e.g., along tracks T1-T6, across an entirety of cell C1 or C2 for the purpose of illustration. Metal regions/segments M0 and/or BM0 having configurations other than that depicted in FIGS. 1A and 1B, e.g., multiple instances of metal region/segment M0 aligned along a single one of tracks T1-T6 or a given one or more of tracks T1-T6 being free from including a metal region/segment M0, are within the scope of the present disclosure.

In accordance with the configurations of cells C1 and C2, instances of frontside gate via region/structure VG overlap/overlie instances of gate G and overlap/underlie instances of metal region/segment M0, instances of frontside S/D via region structure VD overlap/overlie instances of MD region/segment MD and overlap/underlie instances of metal region/segment M0, instances of backside gate via region/structure BVG overlap/overlie instances of gate G and overlap/underlie instances of backside metal region/segment BM0, and instances of backside S/D via region structure BVD overlap/overlie instances of MD region/segment MD and overlap/underlie instances of backside metal region/segment BM0.

As depicted in FIGS. 1A and 1B, an entirety of the instances of via region/structure VG in cell C1 are positioned along one or both of tracks T1 or T2, an entirety of the instances of via region/structure VG in cell C2 are positioned along one or both of tracks T4 or T5, an entirety of the instances of via region/structure VD in cell C1 are positioned along one or both of tracks T2 or T3, and an entirety of the instances of via region/structure VD in cell C2 are positioned along one or both of tracks T5 or T6.

Stated differently, in cell C1, instances of via region VD are prohibited from being positioned along track T1 and instances of via region VG are prohibited from being positioned along track T3 such that an IC device manufactured based on cell C1 is free from including vias VD at a Y direction location along the corresponding instances of isolation structure ISO corresponding to track T1, and free from including vias VG at a Y direction location along the corresponding instances of isolation structure ISO corresponding to track T3.

Similarly, in cell C2, instances of via region VD are prohibited from being positioned along track T4 and instances of via region VG are prohibited from being positioned along track T6 such that an IC device manufactured based on cell C2 is free from including vias VD at a Y direction location along the corresponding instances of isolation structure ISO corresponding to track T4, and free from including vias VG at a Y direction location along the corresponding instances of isolation structure ISO corresponding to track T6.

Accordingly, IC layout diagram 100 including cell C2 abutting cell C1 includes an entirety of via regions VG of cell C1 separated from an entirety of via regions VG of cell C2 by a distance corresponding to track T3 and thereby based on a spacing SVG (equal to twice pitch TP) minus a width (not labeled) of via regions VG along the Y direction, and includes an entirety of via regions VD of cell C1 separated from an entirety of via regions VD of cell C2 by a distance corresponding to track T4 and thereby based on a spacing SVD (equal to twice pitch TP) minus a width (not labeled) of via regions VD along the Y direction.

As further depicted in FIGS. 1A and 1B, via regions VG positioned at tracks T1 and T2 in cell C1 and at tracks T4 and T5 in cell C2, and via regions VD positioned at tracks T2 and T3 in cell C1 and at tracks T5 and T6 in cell C2 are free from being aligned in the Y direction.

Thus, by the configuration discussed above, entireties of each of via regions VG and VD included in cells C1 and C2 in IC layout diagram 100 are separated from each other along the Y direction by at least distances corresponding to one of tracks T1-T6.

The arrangement of two adjacent cells C1 and C2 depicted in FIGS. 1A and 1B is a non-limiting example provided for the purpose of illustration. In some embodiments, IC layout diagram/device 100 includes one or more cells (not shown) in addition to cells C1 and C2. In some embodiments, IC layout diagram/device 100 includes one or more additional cells having via configurations analogous to those of cells C1 and C2 and abutting top border TB of cell C1, bottom border BB of cell C2, and/or one or more of side borders SB, e.g., by sharing an isolation region ISO, such that entireties of each of via regions VG and VD included in IC layout diagram 100 are separated from each other along the Y direction by at least distances corresponding to a lowermost frontside metal layer track, e.g., a track T1-T6.

A mask, e.g., an EUV mask discussed below with respect to IC manufacturing flow 600 and FIG. 6, used to manufacture IC device 100 based on IC layout diagram 100 has a pitch limit, i.e., a minimum spacing between adjacent features, e.g., vias, along a given direction. Because IC layout diagram 100 includes vias VG and VD having the minimum separation along the Y direction discussed above, IC device 100 is capable of including vias VG and VD having the minimum spacing greater than the pitch limit of a single mask, e.g., an EUV mask, and is thereby capable of being manufactured based on IC layout diagram 100 including entireties of via regions VG and VD included in the single mask.

Compared to other approaches in which gate and/or S/D via regions are included in multiple masks, e.g., based on not being prohibited from specified track locations, IC layout diagram/device 100 is thereby capable of reducing manufacturing costs and complexity associated with using more than one mask.

In some embodiments, pitch TP is less than an EUV mask pitch limit ranging from 30 nanometers (nm) to 40 nm, e.g., 35 nm. In some embodiments, pitch TP has a value ranging from 15-25 nm, e.g., 20 nm, corresponding to a cell height value ranging from 45-75 nm, e.g., 70 nm, and each of spacings SVG and SVD has a value ranging from 30-50 nm, e.g., 40 nm.

Further, because IC layout diagram 100 includes vias VG and VD having the minimum separation along the Y direction discussed above, IC layout diagram 100 is capable of including cut-gate regions CPO and cut-MD regions CMD having respective widths WCPO and WCMD greater than those corresponding to approaches in which vias VG and VD are not arranged as discussed above.

Because a given manufacturing process has a minimum process limit for cut-gate and cut-MD regions, IC layout diagram 100 is thereby capable of being used in manufacturing processes having smaller cut-gate and cut-MD process limits than those used to manufacture the IC devices in the other approaches.

In some embodiments, a manufacturing process has minimum cut-gate and cut-MD process limits ranging from 10-20 nm, e.g., 15 nm, and widths WCPO and WCMD have one or more values greater than the process limits.

FIGS. 2A-2C are a schematic diagram of a circuit 200 and plan views of IC layout diagrams/devices 200-1 and 200-2, in accordance with some embodiments. IC layout diagrams/devices 200-1 and 200-2 depicted in respective FIGS. 2B and 2C are non-limiting examples of cells C1 and C2 discussed above with respect to FIGS. 1A and 1B, and are electrically equivalent cells configured in accordance with circuit 200 depicted in FIG. 2A.

As depicted in FIG. 2A, circuit 200 includes power supply node/voltage VDD, reference node/voltage VSS, input terminals/signals A1, A2, B1, and B2, and output terminal/signal ZN. Four PMOS transistors (not labeled for clarity) are positioned between power supply node VDD and output terminal ZN and include gates coupled to input terminals A1, A2, B1, and B2, and four NMOS transistors (not labeled for clarity) are positioned between output terminal ZN and reference node VSS and also include gates coupled to input terminals A1, A2, B1, and B2.

Circuit 200 is thereby configured as an AND-OR-INVERT circuit including four PMOS transistors and four NMOS transistors configured to generate output signal ZN based on input signals A1, A2, B1, and B2.

As depicted in FIGS. 2B and 2C, each of IC layout diagrams/devices 200-1 and 200-2 includes a total of four CFETs corresponding to transistors X1 or X2, discussed above, positioned between isolation structures ISO and including gates G corresponding to input terminals A1, A2, B1, and B2. One of multiple instances of metal region/segment M0 is electrically connected through an instance of via region/structure VIA0 to an instance of metal region/segment M1 configured as output terminal ZN.

IC layout diagram/device 200-1 includes a top border aligned with a power rail configured as power supply node VDD and a bottom border aligned with a power rail configured as reference node VSS, and IC layout diagram/device 200-2 includes a top border aligned with a power rail configured as reference node VSS and a bottom border aligned with a power rail configured as power supply node VDD.

Each of IC layout diagrams/devices 200-1 and 200-2 includes instances of via region/structure VG electrically connected to overlapping/overlying instances of metal region/segment M0 at locations corresponding to first and second tracks of a total of three lowermost frontside metal layer tracks extending in the X direction.

IC layout diagram/device 200-1 includes an instance of via region/structure VD electrically connected to an overlapping/overlying instance of metal region/segment M0 at a location corresponding to the second track, and IC layout diagram/device 200-2 includes an instance of via region/structure VD electrically connected to an overlapping/overlying instance of metal region/segment M0 at a location corresponding to the third track.

Each of IC layout diagrams/devices 200-1 and 200-2 is thereby usable as one of cells C1 or C2 (depending on the configuration of power rails PR1-PR3) discussed above with respect to FIGS. 1A and 1B, and IC layout diagrams/devices 200-1 and 200-2 are thereby capable of realizing the benefits discussed above with respect to IC layout diagram/device 100.

FIG. 3 is a flowchart of method 300 of manufacturing an IC device, in accordance with some embodiments. Method 300 is operable to form some or all of one or more of IC devices 100, 200-1, or 200-2 discussed above with respect to FIGS. 1A-2C.

In some embodiments, performing some or all of the operations of method 300 is part of building a plurality of IC devices, e.g., transistors, logic gates, memory cells, interconnect structures, and/or other suitable devices, by performing a plurality of manufacturing operations, e.g., one or more of a lithography, diffusion, deposition, etching, planarizing, or other operation suitable for building the plurality of IC devices in a semiconductor substrate.

In some embodiments, the operations of method 300 are performed in the order depicted in FIG. 3. In some embodiments, the operations of method 300 are performed in an order other than the order depicted in FIG. 3. In some embodiments, one or more additional operations are performed before, during, and/or after the operations of method 300. In some embodiments, performing some or all of the operations of method 300 includes performing one or more operations as discussed below with respect to IC manufacturing system 600 and FIG. 6.

At operation 302, in some embodiments, a plurality of transistors is constructed including gates and MD segments between first and second isolation structures in a semiconductor substrate. In some embodiments, constructing the plurality of transistors includes constructing instances of one or both of CFETs X1 or X2 between instances of isolation structures ISO discussed above with respect to FIGS. 1A-2C.

Constructing the plurality of transistors includes arranging the plurality of transistors in accordance with one or more electrical functions, e.g., corresponding to cells C1 and/or C2 discussed above with respect to FIGS. 1A and 1B. In some embodiments, constructing the plurality of transistors includes arranging the plurality of transistors in accordance with electrically equivalent functions, e.g., corresponding to IC layout diagrams/devices 200-1 and 200-2 discussed above with respect to FIGS. 2A-2C.

Forming the plurality of frontside gate vias includes performing a plurality of manufacturing processes including one or more of a lithography, diffusion, implantation, deposition, plasma treatment, etching, planarizing, spin coating, soft-baking, exposure, post-baking, developing, rinsing, drying, or other suitable operation.

At operation 304, a plurality of frontside gate vias is formed on the gates at locations corresponding to first and/or second tracks of a total of three lowermost frontside metal layer tracks. In some embodiments, forming the plurality of frontside gate vias includes forming via structures VG at locations corresponding to tracks T1 and/or T2 discussed above with respect to FIGS. 1A-2C.

In some embodiments, forming the plurality of frontside gate vias includes forming at least a second plurality of frontside gate vias, e.g., via structures VG at locations corresponding to tracks T4 and/or T5 discussed above with respect to FIGS. 1A-2C.

In some embodiments, forming the plurality of frontside gate vias includes performing a plurality of manufacturing operations including depositing and patterning one or more photoresist layers, performing one or more etching processes, and performing one or more deposition processes whereby one or more conductive materials are configured to form a plurality of continuous, low resistance structures.

In some embodiments, forming the plurality of frontside gate vias includes using a single mask, e.g., a single EUV mask.

At operation 306, a plurality of frontside S/D vias is formed on the MD segments at locations corresponding to second and/or third tracks of the three lowermost frontside metal layer tracks. In some embodiments, forming the plurality of frontside S/D vias includes forming via structures VD at locations corresponding to tracks T2 and/or T3 discussed above with respect to FIGS. 1A-2C.

In some embodiments, forming the plurality of frontside S/D vias includes forming at least a second plurality of frontside S/D vias, e.g., via structures VD at locations corresponding to tracks T5 and/or T6 discussed above with respect to FIGS. 1A-2C.

Forming the plurality of frontside S/D vias includes performing a plurality of manufacturing operations including depositing and patterning one or more photoresist layers, performing one or more etching processes, and performing one or more deposition processes whereby one or more conductive materials are configured to form a plurality of continuous, low resistance structures.

In some embodiments, forming the plurality of frontside S/D vias includes using a single mask, e.g., the single (EUV) mask used to form the plurality of frontside gate vias in operation 304.

At operation 308, in some embodiments, a plurality of metal segments is formed in the lowermost frontside metal layer electrically connected to the frontside gate and S/D vias. Forming the plurality of metal segments includes forming the plurality of metal segments at locations corresponding to at least one of the three lowermost frontside metal layer tracks.

In some embodiments, forming the plurality of metal segments includes forming metal segments M0 electrically connected to gate vias VG and S/D vias VD at one or more of tracks T1-T3 and/or at one or more of tracks T4-T6 discussed above with respect to FIGS. 1A-2C.

In some embodiments, forming the plurality of metal segments includes forming a plurality of backside metal segments, e.g., backside metal segments BM0 and/or power rails PR1-PR3 discussed above with respect to FIGS. 1A-2C.

Forming the plurality of metal segments includes performing a plurality of manufacturing operations including depositing and patterning one or more photoresist layers, performing one or more etching processes, and performing one or more deposition processes whereby one or more conductive materials are configured to form a plurality of continuous, low resistance structures.

By performing some or all of the operations of method 300, an IC device is manufactured in which an entirety of frontside gate vias are positioned at locations corresponding to first and second lowermost frontside metal tracks and an entirety of frontside S/D vias are positioned at locations corresponding to second and third lowermost frontside metal tracks, thereby enabling the realization of the benefits discussed above with respect to IC devices 100, 200-1, and 200-2.

FIG. 4 is a flowchart of method 400 of generating an IC layout diagram, e.g., one or more of IC layout diagrams 100, 200-1, or 200-2 discussed above with respect to FIGS. 1A-2C, in accordance with some embodiments.

In some embodiments, generating the IC layout diagram includes generating the IC layout diagram corresponding to an IC device, e.g., IC device 100, 200-1, or 200-2 discussed above with respect to FIGS. 1A-2C, manufactured based on the generated IC layout diagram.

In some embodiments, some or all of method 400 is executed by a processor of a computer, e.g., a processor 502 of an IC layout diagram generation system 500, discussed below with respect to FIG. 5.

Some or all of the operations of method 400 are capable of being performed as part of a design procedure performed in a design house, e.g., a design house 620 discussed below with respect to FIG. 6.

In some embodiments, the operations of method 400 are performed in the order depicted in FIG. 4. In some embodiments, the operations of method 400 are performed simultaneously and/or in an order other than the order depicted in FIG. 4. In some embodiments, one or more operations are performed before, between, during, and/or after performing one or more operations of method 400.

At operation 402, in some embodiments, a plurality of transistors including gate and MD regions is arranged in a cell. In some embodiments, arranging the plurality of transistors including gate and MD regions in the cell includes arranging instances of one or both of CFETs X1 or X2 including gate regions G and MD regions MD in cells C1 and/or C2 discussed above with respect to FIGS. 1A-2C.

Arranging the plurality of transistors includes arranging the plurality of transistors in accordance with one or more electrical functions, e.g., corresponding to cells C1 and/or C2 discussed above with respect to FIGS. 1A and 1B. In some embodiments, arranging the plurality of transistors includes arranging the plurality of transistors in accordance with electrically equivalent functions, e.g., corresponding to IC layout diagrams 200-1 and 200-2 discussed above with respect to FIGS. 2A-2C.

At operation 404, in some embodiments, the gate regions are overlapped with gate vias at first and/or second tracks of a total of three lowermost frontside metal layer tracks in the cell. In some embodiments, overlapping the gate regions with the gate vias at the first and/or second tracks includes overlapping gate regions G with via regions VG at tracks T1 and/or T2 in cell C1 discussed above with respect to FIGS. 1A-2C.

In some embodiments, overlapping the gate regions with the gate vias at the first and/or second tracks includes overlapping gate regions G with via regions VG at tracks T4 and/or T5 in cell C2 discussed above with respect to FIGS. 1A-2C.

In some embodiments, overlapping the gate regions with the gate vias includes the gate vias being included in a single mask, e.g., an EUV mask.

At operation 406, in some embodiments, the MD regions are overlapped with S/D vias at second and/or third tracks of the three lowermost frontside metal layer tracks in the cell. In some embodiments, overlapping the MD regions with the S/D vias at the second and/or third tracks includes overlapping MD regions MD with via regions VD at tracks T2 and/or T3 in cell C1 discussed above with respect to FIGS. 1A-2C.

In some embodiments, overlapping the MD regions with the S/D vias at the second and/or third tracks includes overlapping MD regions MD with via regions VD at tracks T5 and/or T6 in cell C2 discussed above with respect to FIGS. 1A-2C.

In some embodiments, overlapping the MD regions with the S/D vias includes the S/D vias being included in a single mask, e.g., the single (EUV) mask that includes the gate vias positioned in operation 404.

At operation 408, in some embodiments, the gate and S/D vias are overlapped with metal regions in the lowermost frontside metal layer. Overlapping the gate and S/D vias includes overlapping the gate and S/D regions with the metal regions along at least one of the three lowermost frontside metal layer tracks.

In some embodiments, overlapping the gate and S/D vias includes overlapping gate vias VG and S/D vias VD with metal regions M0 at one or more of tracks T1-T3 and/or at one or more of tracks T4-T6 discussed above with respect to FIGS. 1A-2C.

In some embodiments, overlapping the gate and S/D vias includes overlapping the gates and MD regions with backside via and metal regions, e.g., overlapping gate G and MD regions MD with backside vias BVG and BVD and backside metal regions BM0 discussed above with respect to FIGS. 1A-2C.

At operation 410, in some embodiments, the cell is abutted with a second cell in an IC layout diagram. In some embodiments, abutting the cell with the second cell includes abutting cell C1 with cell C2 in IC layout diagram 100 discussed above with respect to FIGS. 1A and 1B.

In some embodiments, abutting the cell with the second cell includes abutting one or more additional cells with one or more additional second cells.

In some embodiments, abutting the cell with the second cell includes generating the cell and/or the second cell by performing some or all of operations 402-408 discussed above. In some embodiments, abutting the cell with the second cell includes retrieving one or both of the cell or the second from a storage device, e.g., a cell library 507 discussed below with respect to FIG. 5.

At operation 412, in some embodiments, the IC layout diagram including the cell(s) is stored in a storage device. In some embodiments, storing the IC layout diagram in the storage device includes storing one or more of cells C1 or C2 or IC layout diagrams 100, 200-1, or 200-2, discussed above with respect to FIGS. 1A-2C, in the storage device.

In some embodiments, storing the IC layout diagram in the storage device includes storing the IC layout diagram in a non-volatile, computer-readable memory or a database, and/or includes storing the IC layout diagram over a network. In some embodiments, storing the IC layout diagram in the storage device includes storing the IC layout diagram in cell library 507 or layout diagrams 509 and/or over network 514 of IC layout diagram generation system 500, discussed below with respect to FIG. 5.

At operation 414, in some embodiments, one or more manufacturing operations, one or more lithographic exposures, are performed based on the IC layout diagram. Non-limiting examples of performing one or more manufacturing operations, e.g., one or more lithographic exposures, based on the IC layout diagram are discussed above with respect to FIG. 3 and below with respect to FIG. 6.

By executing some or all of the operations of method 400, an IC layout diagram is generated corresponding to an IC device in which an entirety of frontside gate vias are positioned at locations corresponding to first and second lowermost frontside metal tracks and an entirety of frontside S/D vias are positioned at locations corresponding to second and third lowermost frontside metal tracks, thereby enabling the realization of the benefits discussed above with respect to IC devices 100, 200-1, and 200-2.

FIG. 5 is a block diagram of IC layout diagram generation system 500, in accordance with some embodiments. Methods described herein of designing IC layout diagrams in accordance with one or more embodiments are implementable, for example, using IC layout diagram generation system 500, in accordance with some embodiments.

In some embodiments, IC layout diagram generation system 500 is a general purpose computing device including a hardware processor 502 and a non-transitory, computer-readable storage medium 504. Storage medium 504, amongst other things, is encoded with, i.e., stores, computer program code 506, i.e., a set of executable instructions. Execution of instructions 506 by hardware processor 502 represents (at least in part) an electronic design automation (EDA) tool which implements a portion or all of a method, e.g., method 400 of generating an IC layout diagram described above with respect to FIG. 4 (hereinafter, the noted processes and/or methods).

Processor 502 is electrically coupled to computer-readable storage medium 504 via a bus 508. Processor 502 is also electrically coupled to an I/O interface 510 by bus 508. A network interface 512 is also electrically connected to processor 502 via bus 508. Network interface 512 is connected to a network 514, so that processor 502 and computer-readable storage medium 504 are capable of connecting to external elements via network 514. Processor 502 is configured to execute computer program code 506 encoded in computer-readable storage medium 504 in order to cause IC layout diagram generation system 500 to be usable for performing a portion or all of the noted processes and/or methods. In one or more embodiments, processor 502 is a central processing unit (CPU), a multi-processor, a distributed processing system, an application specific integrated circuit (ASIC), and/or a suitable processing unit.

In one or more embodiments, computer-readable storage medium 504 is an electronic, magnetic, optical, electromagnetic, infrared, and/or a semiconductor system (or apparatus or device). For example, computer-readable storage medium 504 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 504 includes a compact disk-read only memory (CD-ROM), a compact disk-read/write (CD-R/W), and/or a digital video disc (DVD).

In one or more embodiments, computer-readable storage medium 504 stores computer program code 506 configured to cause IC layout diagram generation system 500 (where such execution represents (at least in part) the EDA tool) to be usable for performing a portion or all of the noted processes and/or methods. In one or more embodiments, computer-readable storage medium 504 also stores information which facilitates performing a portion or all of the noted processes and/or methods.

In one or more embodiments, computer-readable storage medium 504 stores cell library 507 of cells including such cells as disclosed herein, e.g., memory cell 112 of IC layout diagrams 200-400 discussed above with respect to FIGS. 1-5D.

In one or more embodiments, computer-readable storage medium 504 stores layout diagrams 509 including such IC layout diagrams as disclosed herein, e.g., IC layout diagrams 100, 200-1, and 200-2 discussed above with respect to FIGS. 1A-3C.

IC layout diagram generation system 500 includes I/O interface 510. I/O interface 510 is coupled to external circuitry. In one or more embodiments, I/O interface 510 includes a keyboard, keypad, mouse, trackball, trackpad, touchscreen, and/or cursor direction keys for communicating information and commands to processor 502.

IC layout diagram generation system 500 also includes network interface 512 coupled to processor 502. Network interface 512 allows system 500 to communicate with network 514, to which one or more other computer systems are connected. Network interface 512 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more IC layout diagram generation systems 500.

IC layout diagram generation system 500 is configured to receive information through I/O interface 510. The information received through I/O interface 510 includes one or more of instructions, data, design rules, libraries of standard cells, and/or other parameters for processing by processor 502. The information is transferred to processor 502 via bus 508. IC layout diagram generation system 500 is configured to receive information related to a UI through I/O interface 510. The information is stored in computer-readable medium 504 as user interface (UI) 542.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by IC layout diagram generation system 500. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 6 is a block diagram of IC manufacturing system 600, and an IC manufacturing flow associated therewith, in accordance with some embodiments. In some embodiments, based on an IC layout diagram, at least one of (A) one or more semiconductor masks or (B) at least one component in a layer of a semiconductor integrated circuit is fabricated using manufacturing system 600.

In FIG. 6, IC manufacturing system 600 includes entities, such as a design house 620, a mask house 630, and an IC manufacturer/fabricator (“fab”) 650, that interact with one another in the design, development, and manufacturing cycles and/or services related to manufacturing an IC device 660. The entities in system 600 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 620, mask house 630, and IC fab 650 is owned by a single larger company. In some embodiments, two or more of design house 620, mask house 630, and IC fab 650 coexist in a common facility and use common resources.

Design house (or design team) 620 generates an IC design layout diagram 622. IC design layout diagram 622 includes various geometrical patterns, e.g., one or more of IC layout diagrams 100, 200-1, or 200-2 discussed above with respect to FIGS. 1A-3C. The geometrical patterns correspond to patterns of metal, oxide, or semiconductor layers that make up the various components of IC device 660 to be fabricated. The various layers combine to form various IC features. For example, a portion of IC design layout diagram 622 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 620 implements a proper design procedure to form IC design layout diagram 622. The design procedure includes one or more of logic design, physical design or place and route. IC design layout diagram 622 is presented in one or more data files having information of the geometrical patterns. For example, IC design layout diagram 622 can be expressed in a GDSII file format or DFII file format.

Mask house 630 includes data preparation 632 and mask fabrication 644. Mask house 630 uses IC design layout diagram 622 to manufacture one or more masks 645 to be used for fabricating the various layers of IC device 660 according to IC design layout diagram 622. Mask house 630 performs mask data preparation 632, where IC design layout diagram 622 is translated into a representative data file (RDF). Mask data preparation 632 provides the RDF to mask fabrication 644. Mask fabrication 644 includes a mask writer. A mask writer converts the RDF to an image on a substrate, such as a mask (reticle) 645 or a semiconductor wafer 653. The design layout diagram 622 is manipulated by mask data preparation 632 to comply with particular characteristics of the mask writer and/or requirements of IC fab 650. In FIG. 6, mask data preparation 632 and mask fabrication 644 are illustrated as separate elements. In some embodiments, mask data preparation 632 and mask fabrication 644 can be collectively referred to as mask data preparation.

In some embodiments, mask data preparation 632 includes optical proximity correction (OPC) which uses lithography enhancement techniques to compensate for image errors, such as those that can arise from diffraction, interference, other process effects and the like. OPC adjusts IC design layout diagram 622. In some embodiments, mask data preparation 632 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 632 includes a mask rule checker (MRC) that checks the IC design layout diagram 622 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 622 to compensate for limitations during mask fabrication 644, which may undo part of the modifications performed by OPC in order to meet mask creation rules.

In some embodiments, mask data preparation 632 includes lithography process checking (LPC) that simulates processing that will be implemented by IC fab 650 to fabricate IC device 660. LPC simulates this processing based on IC design layout diagram 622 to create a simulated manufactured device, such as IC device 660. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 622.

It should be understood that the above description of mask data preparation 632 has been simplified for the purposes of clarity. In some embodiments, data preparation 632 includes additional features such as a logic operation (LOP) to modify the IC design layout diagram 622 according to manufacturing rules. Additionally, the processes applied to IC design layout diagram 622 during data preparation 632 may be executed in a variety of different orders.

After mask data preparation 632 and during mask fabrication 644, a mask 645 or a group of masks 645 are fabricated based on the modified IC design layout diagram 622. In some embodiments, mask fabrication 644 includes performing one or more lithographic exposures based on IC design layout diagram 622. In some embodiments, an electron-beam (e-beam) or a mechanism of multiple e-beams is used to form a pattern on a mask (photomask or reticle) 645 based on the modified IC design layout diagram 622. Mask 645 can be formed in various technologies. In some embodiments, mask 645 is formed using binary technology. In some embodiments, a mask pattern includes opaque regions and transparent regions. A radiation beam, such as an ultraviolet (UV) or EUV beam, used to expose the image sensitive material layer (e.g., photoresist) which has been coated on a wafer, is blocked by the opaque region and transmits through the transparent regions. In one example, a binary mask version of mask 645 includes a transparent substrate (e.g., fused quartz) and an opaque material (e.g., chromium) coated in the opaque regions of the binary mask. In another example, mask 645 is formed using a phase shift technology. In a phase shift mask (PSM) version of mask 645, various features in the pattern formed on the phase shift mask are configured to have proper phase difference to enhance the resolution and imaging quality. In various examples, the phase shift mask can be attenuated PSM or alternating PSM. The mask(s) generated by mask fabrication 644 is used in a variety of processes. For example, such a mask(s) is used in an ion implantation process to form various doped regions in semiconductor wafer 653, in an etching process to form various etching regions in semiconductor wafer 653, and/or in other suitable processes.

IC fab 650 is an IC fabrication business that includes one or more manufacturing facilities for the fabrication of a variety of different IC products. In some embodiments, IC Fab 650 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 650 includes wafer fabrication tools 652 configured to execute various manufacturing operations on semiconductor wafer 653 such that IC device 660 is fabricated in accordance with the mask(s), e.g., mask 645. In various embodiments, fabrication tools 652 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 650 uses mask(s) 645 fabricated by mask house 630 to fabricate IC device 660. Thus, IC fab 650 at least indirectly uses IC design layout diagram 622 to fabricate IC device 660. In some embodiments, semiconductor wafer 653 is fabricated by IC fab 650 using mask(s) 645 to form IC device 660. In some embodiments, the IC fabrication includes performing one or more lithographic exposures based at least indirectly on IC design layout diagram 622. Semiconductor wafer 653 includes a silicon substrate or other proper substrate having material layers formed thereon. Semiconductor wafer 653 further includes one or more of various doped regions, dielectric features, multilevel interconnects, and the like (formed at subsequent manufacturing steps).

In some embodiments, an IC device includes first and second isolation structures extending between first and second locations along a first direction in a front side of a semiconductor substrate, a first plurality of transistors including first pluralities of gates and MD segments extending between the first and second locations in the first direction and being entireties of gates and MD segments positioned between the first and second locations and between the first and second isolation structures in a second direction perpendicular to the first direction, a first plurality of frontside gate vias being an entirety of frontside gate vias electrically connected to the first plurality of gates, and a first plurality of frontside S/D vias being an entirety of frontside S/D vias electrically connected to the first plurality of MD segments. An entirety of the frontside gate vias are positioned at locations corresponding to first and/or second tracks of first through third lowermost frontside metal layer tracks extending in the second direction, being aligned in order between the first and second locations, and being an entirety of lowermost frontside metal layer tracks positioned between the first and second locations, and an entirety of the frontside S/D vias are positioned at locations corresponding to the second and/or third tracks. In some embodiments, the IC device includes a first plurality of metal segments extending in the second direction in the lowermost frontside metal layer of the semiconductor substrate, positioned at locations corresponding to two or more of the first through third tracks, and electrically connected to the pluralities of frontside gate vias and frontside S/D vias. In some embodiments, the IC device includes first and second power rails extending in the second direction in a lowermost backside metal layer of the semiconductor substrate at the respective first and second locations, wherein the first power rail is configured to have one of a power supply voltage or a reference voltage, and the second power rail is configured to have the other of the power supply voltage or the reference voltage, a first plurality of backside metal segments extending in the second direction in the lowermost backside metal layer between the first and second power rails, and first pluralities of backside gate vias and backside S/D vias electrically connected to the first plurality of backside metal segments and to the corresponding first pluralities of gates and MD segments. In some embodiments, the IC device includes third and fourth isolation structures extending in the first direction in the front side of the semiconductor substrate between the second location and a third location along the first direction, a second plurality of transistors including second pluralities of gates and MD segments extending between the second and third locations in the first direction and being entireties of gates and MD segments positioned between the second and third locations and between the third and fourth isolation structures, a second plurality of frontside gate vias being an entirety of frontside gate vias electrically connected to the second plurality of gates, a second plurality of frontside S/D vias being an entirety of frontside S/D vias electrically connected to the second plurality of MD segments, a second plurality of metal segments extending in the second direction in the lowermost frontside metal layer, a third power rail extending in the second direction in the lowermost backside metal layer at the third location and configured to have the one of the power supply voltage or the reference voltage, a second plurality of backside metal segments extending in the second direction in the lowermost backside metal layer between the second and third power rails, and second pluralities of backside gate vias and backside S/D vias electrically connected to the second plurality of backside metal segments and to the corresponding second pluralities of gates and MD segments, wherein the second plurality of metal segments are positioned at locations corresponding to two or more of fourth through sixth lowermost frontside metal layer tracks aligned in order between the second and third locations, the fourth through sixth tracks are an entirety of lowermost frontside metal layer tracks positioned between the second and third locations, an entirety of the second plurality of frontside gate vias are electrically connected to metal segments of the second plurality of metal segments at locations corresponding to the fourth and/or fifth tracks, and an entirety of the second plurality of frontside S/D vias are electrically connected to metal segments of the second plurality of metal segments at locations corresponding to the fifth and/or sixth tracks. In some embodiments, the first plurality of transistors is configured to perform a first logical function, and the second plurality of transistors is configured to perform a second logical function. In some embodiments, the third and fourth isolation structures are aligned with the first and second isolation structures, and the first and second logical functions are an electrically equivalent function. In some embodiments, each of a minimum spacing between frontside gate vias of the first plurality of frontside gate vias and frontside gate vias of the second plurality of frontside gate vias and a minimum spacing between frontside S/D vias of the first plurality of frontside S/D vias and frontside S/D vias of the second plurality of frontside S/D vias is greater than a minimum spacing limit of an EUV mask corresponding to the IC device. In some embodiments, the first plurality of transistors comprises CFETs.

In some embodiments, a method of generating an IC layout diagram includes arranging a plurality of transistors in a cell by extending pluralities of gate regions and MD regions in a cell height direction between top and bottom cell borders corresponding to the cell height, the gate and MD regions being entireties of gate and MD regions included in the cell, overlapping the plurality of gate regions with a plurality of frontside gate vias being an entirety of frontside gate vias overlapping the plurality of gate regions, overlapping the plurality of MD regions with a plurality of frontside S/D vias being an entirety of frontside S/D vias overlapping the plurality of MD regions, and storing the IC layout diagram comprising the cell in a storage device. The cell includes a total of three lowermost frontside metal layer tracks aligned in order from first through third tracks from the top cell border to the bottom cell border, overlapping the plurality of gate regions with the plurality of frontside gate vias includes positioning all of the plurality of frontside gate vias along the first and/or second tracks, and overlapping the plurality of MD regions with the plurality of frontside S/D vias includes positioning all of the plurality of frontside S/D vias along the second and/or third tracks. In some embodiments, the method includes overlapping the pluralities of gate regions and MD regions with a plurality of metal regions of the lowermost frontside metal layer by aligning the plurality of metal regions along at least two of the first through third tracks. In some embodiments, overlapping the plurality of gate regions with the plurality of frontside gate vias and the plurality of MD regions with the plurality of frontside S/D vias includes entireties of the pluralities of frontside gate vias and frontside S/D vias being included in a single EUV mask. In some embodiments, the cell is a first cell, the method includes positioning the first cell in the IC layout diagram by aligning the top and bottom cell borders with respective first and second backside power rails and positioning a second cell in the IC layout diagram by abutting a corresponding top second cell border with the bottom first cell border and aligning a corresponding bottom second cell border with a third backside power rail, each of the first and third backside power rails is configured to have one of a power supply voltage or a reference voltage, the second backside power rail is configured to have the other of the power supply voltage or the reference voltage, the second cell includes a total of three lowermost frontside metal layer tracks aligned in order from fourth through sixth tracks from the top second cell border to the bottom second cell border, all of a second plurality of frontside gate vias of the second cell are positioned along the fourth and/or fifth tracks, all of a second plurality of frontside S/D vias of the second cell are positioned along the fifth and/or sixth tracks, and storing the IC layout diagram in the storage device includes storing the IC layout diagram comprising the second cell. In some embodiments, entireties of the pluralities of frontside gate vias and frontside S/D vias of the first and second cells are included in a single extreme EUV mask. In some embodiments, the first and second cells include electrically equivalent cells. In some embodiments, arranging the plurality of transistors includes extending pluralities of gate regions and MD regions of CFETs.

In some embodiments, a method of manufacturing an IC device includes constructing first and second isolation structures and a first plurality of transistors including first pluralities of gates and MD segments positioned between the first and second isolation structures, wherein the first and second isolation structures and first pluralities of gates and MD segments extend between first and second locations in a first direction in a front side of a semiconductor substrate and are an entirety of gates and MD segments positioned between the first and second locations and between the first and second isolation structures in a second direction perpendicular to the first direction, forming a first plurality of frontside gate vias being an entirety of frontside gate vias electrically connected to the first plurality of gates, and forming a first plurality of frontside S/D vias being an entirety of frontside S/D vias electrically connected to the first plurality of MD segments. Forming the first plurality of frontside gate vias includes forming an entirety of the frontside gate vias at locations corresponding to first and/or second tracks of first through third lowermost frontside metal layer tracks extending in the second direction, the first through third tracks being aligned in order between the first and second locations and being an entirety of lowermost frontside metal layer tracks aligned between the first and second locations, and forming the first plurality of frontside S/D vias includes forming an entirety of the frontside S/D vias at locations corresponding to the second and/or third tracks. In some embodiments, forming the first pluralities of frontside gate vias and frontside S/D vias includes using a single extreme EUV mask. In some embodiments, the method includes forming a plurality of metal segments extending in the second direction in the lowermost frontside metal layer of the semiconductor substrate, positioned at locations corresponding to two or more of the first through third tracks, and electrically connected to the pluralities of frontside gate vias and frontside S/D vias. In some embodiments, constructing the first and second isolation structures and first plurality of transistors includes constructing third and fourth isolation structures and a second plurality of transistors including second pluralities of gates and MD segments positioned between the third and fourth isolation structures, wherein the third and fourth isolation structures and the second pluralities of gates and MD segments extend between the second location and a third location in the first direction and are an entirety of gates and MD segments positioned between the second and third locations and between the third and fourth isolation structures in the second direction, forming the first plurality of frontside gate vias includes forming a second plurality of frontside gate vias being an entirety of frontside gate vias electrically connected to the second plurality of gates, forming the first plurality of frontside S/D vias includes forming a second plurality of frontside S/D vias being an entirety of frontside S/D vias electrically connected to the second plurality of MD segments, forming the second plurality of frontside gate vias includes forming an entirety of the frontside gate vias at locations corresponding to fourth and/or fifth tracks of fourth through sixth lowermost frontside metal layer tracks extending in the second direction, the fourth through sixth tracks being aligned in order between the second and third locations and being an entirety of lowermost frontside metal layer tracks aligned between the second and third locations, and forming the second plurality of frontside S/D vias includes forming an entirety of the frontside S/D vias at locations corresponding to the fifth and/or sixth tracks. In some embodiments, constructing the first plurality of transistors includes constructing CFETs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device comprising:
first and second isolation structures extending between first and second locations along a first direction in a front side of a semiconductor substrate;
a first plurality of transistors comprising first pluralities of gates and metal-like defined (MD) segments extending between the first and second locations in the first direction and being entireties of gates and MD segments positioned between the first and second locations and between the first and second isolation structures in a second direction perpendicular to the first direction;
a first plurality of frontside gate vias being an entirety of frontside gate vias electrically connected to the first plurality of gates; and
a first plurality of frontside source/drain (S/D) vias being an entirety of frontside S/D vias electrically connected to the first plurality of MD segments,
wherein
an entirety of the frontside gate vias are positioned at locations corresponding to first and/or second tracks of first through third lowermost frontside metal layer tracks extending in the second direction, being aligned in order between the first and second locations, and being an entirety of lowermost frontside metal layer tracks positioned between the first and second locations, and
an entirety of the frontside S/D vias are positioned at locations corresponding to the second and/or third tracks.

2. The IC device of claim 1, further comprising:
a first plurality of metal segments extending in the second direction in the lowermost frontside metal layer of the semiconductor substrate, positioned at locations corresponding to two or more of the first through third tracks, and electrically connected to the pluralities of frontside gate vias and frontside S/D vias.

3. The IC device of claim 2, further comprising:
first and second power rails extending in the second direction in a lowermost backside metal layer of the semiconductor substrate at the respective first and second locations, wherein
the first power rail is configured to have one of a power supply voltage or a reference voltage, and
the second power rail is configured to have the other of the power supply voltage or the reference voltage;
a first plurality of backside metal segments extending in the second direction in the lowermost backside metal layer between the first and second power rails; and
first pluralities of backside gate vias and backside S/D vias electrically connected to the first plurality of backside metal segments and to the corresponding first pluralities of gates and MD segments.

4. The IC device of claim 3, further comprising:
third and fourth isolation structures extending in the first direction in the front side of the semiconductor substrate between the second location and a third location along the first direction;
a second plurality of transistors comprising second pluralities of gates and MD segments extending between the second and third locations in the first direction and being entireties of gates and MD segments positioned between the second and third locations and between the third and fourth isolation structures;
a second plurality of frontside gate vias being an entirety of frontside gate vias electrically connected to the second plurality of gates;
a second plurality of frontside S/D vias being an entirety of frontside S/D vias electrically connected to the second plurality of MD segments;
a second plurality of metal segments extending in the second direction in the lowermost frontside metal layer;
a third power rail extending in the second direction in the lowermost backside metal layer at the third location and configured to have the one of the power supply voltage or the reference voltage;
a second plurality of backside metal segments extending in the second direction in the lowermost backside metal layer between the second and third power rails; and
second pluralities of backside gate vias and backside S/D vias electrically connected to the second plurality of backside metal segments and to the corresponding second pluralities of gates and MD segments,
wherein
the second plurality of metal segments are positioned at locations corresponding to two or more of fourth through sixth lowermost frontside metal layer tracks aligned in order between the second and third locations,
the fourth through sixth tracks are an entirety of lowermost frontside metal layer tracks positioned between the second and third locations,
an entirety of the second plurality of frontside gate vias are electrically connected to metal segments of the second plurality of metal segments at locations corresponding to the fourth and/or fifth tracks, and
an entirety of the second plurality of frontside S/D vias are electrically connected to metal segments of the second plurality of metal segments at locations corresponding to the fifth and/or sixth tracks.

5. The IC device of claim 4, wherein
the first plurality of transistors is configured to perform a first logical function, and
the second plurality of transistors is configured to perform a second logical function.

6. The IC device of claim 5, wherein
the third and fourth isolation structures are aligned with the first and second isolation structures, and
the first and second logical functions are an electrically equivalent function.

7. The IC device of claim 4, wherein
each of a minimum spacing between frontside gate vias of the first plurality of frontside gate vias and frontside gate vias of the second plurality of frontside gate vias and a minimum spacing between frontside S/D vias of the first plurality of frontside S/D vias and frontside S/D vias of the second plurality of frontside S/D vias is greater than a minimum spacing limit of an extreme ultraviolet (EUV) mask corresponding to the IC device.

8. The IC device of claim 1, wherein
the first plurality of transistors comprises complementary field-effect transistors (CFETs).

9. A method of generating an integrated circuit (IC) layout diagram, the method comprising:
arranging a plurality of transistors in a cell by extending pluralities of gate regions and metal-like defined (MD) regions in a cell height direction between top and bottom cell borders corresponding to the cell height, the gate and MD regions being entireties of gate and MD regions included in the cell;
overlapping the plurality of gate regions with a plurality of frontside gate vias being an entirety of frontside gate vias overlapping the plurality of gate regions;
overlapping the plurality of MD regions with a plurality of frontside source/drain (S/D) vias being an entirety of frontside S/D vias overlapping the plurality of MD regions; and
storing the IC layout diagram comprising the cell in a storage device,
wherein
the cell comprises a total of three lowermost frontside metal layer tracks aligned in order from first through third tracks from the top cell border to the bottom cell border,
the overlapping the plurality of gate regions with the plurality of frontside gate vias comprises positioning all of the plurality of frontside gate vias along the first and/or second tracks, and
the overlapping the plurality of MD regions with the plurality of frontside S/D vias comprises positioning all of the plurality of frontside S/D vias along the second and/or third tracks.

10. The method of claim 9, further comprising:
overlapping the pluralities of gate regions and MD regions with a plurality of metal regions of the lowermost frontside metal layer by aligning the plurality of metal regions along at least two of the first through third tracks.

11. The method of claim 9, wherein
the overlapping the plurality of gate regions with the plurality of frontside gate vias and the plurality of MD regions with the plurality of frontside S/D vias comprises entireties of the pluralities of frontside gate vias and frontside S/D vias being included in a single extreme ultraviolet (EUV) mask.

12. The method of claim 9, wherein
the cell is a first cell,
the method further comprises:
positioning the first cell in the IC layout diagram by aligning the top and bottom cell borders with respective first and second backside power rails; and
positioning a second cell in the IC layout diagram by abutting a corresponding top second cell border with the bottom first cell border and aligning a corresponding bottom second cell border with a third backside power rail,
each of the first and third backside power rails is configured to have one of a power supply voltage or a reference voltage,
the second backside power rail is configured to have the other of the power supply voltage or the reference voltage,
the second cell comprises a total of three lowermost frontside metal layer tracks aligned in order from fourth through sixth tracks from the top second cell border to the bottom second cell border,
all of a second plurality of frontside gate vias of the second cell are positioned along the fourth and/or fifth tracks,
all of a second plurality of frontside S/D vias of the second cell are positioned along the fifth and/or sixth tracks, and
the storing the IC layout diagram in the storage device comprises storing the IC layout diagram comprising the second cell.

13. The method of claim 12, wherein
entireties of the pluralities of frontside gate vias and frontside S/D vias of the first and second cells are included in a single extreme ultraviolet (EUV) mask.

14. The method of claim 12, wherein
the first and second cells comprise electrically equivalent cells.

15. The method of claim 9, wherein
the arranging the plurality of transistors comprises extending pluralities of gate regions and MD regions of complementary field-effect transistors (CFETs).

16. A method of manufacturing an integrated circuit (IC) device, the method comprising:
constructing first and second isolation structures and a first plurality of transistors comprising first pluralities of gates and metal-like defined (MD) segments positioned between the first and second isolation structures,
wherein the first and second isolation structures and first pluralities of gates and MD segments extend between first and second locations in a first direction in a front side of a semiconductor substrate and are an entirety of gates and MD segments positioned between the first and second locations and between the first and second isolation structures in a second direction perpendicular to the first direction;
forming a first plurality of frontside gate vias being an entirety of frontside gate vias electrically connected to the first plurality of gates; and
forming a first plurality of frontside source/drain (S/D) vias being an entirety of frontside S/D vias electrically connected to the first plurality of MD segments,
wherein
the forming the first plurality of frontside gate vias comprises forming an entirety of the frontside gate vias at locations corresponding to first and/or second tracks of first through third lowermost frontside metal layer tracks extending in the second direction, the first through third tracks being aligned in order between the first and second locations and being an entirety of lowermost frontside metal layer tracks aligned between the first and second locations, and
the forming the first plurality of frontside S/D vias comprises forming an entirety of the frontside S/D vias at locations corresponding to the second and/or third tracks.

17. The method of claim 16, wherein
the forming the first pluralities of frontside gate vias and frontside S/D vias comprises using a single extreme ultraviolet (EUV) mask.

18. The method of claim 16, further comprising:
forming a plurality of metal segments extending in the second direction in the lowermost frontside metal layer of the semiconductor substrate, positioned at locations corresponding to two or more of the first through third tracks, and electrically connected to the pluralities of frontside gate vias and frontside S/D vias.

19. The method of claim 16, wherein
the constructing the first and second isolation structures and first plurality of transistors comprises constructing third and fourth isolation structures and a second plurality of transistors comprising second pluralities of gates and MD segments positioned between the third and fourth isolation structures,
wherein the third and fourth isolation structures and the second pluralities of gates and MD segments extend between the second location and a third location in the first direction and are an entirety of gates and MD segments positioned between the second and third locations and between the third and fourth isolation structures in the second direction,
the forming the first plurality of frontside gate vias comprises forming a second plurality of frontside gate vias being an entirety of frontside gate vias electrically connected to the second plurality of gates,
the forming the first plurality of frontside S/D vias comprises forming a second plurality of frontside S/D vias being an entirety of frontside S/D vias electrically connected to the second plurality of MD segments,
the forming the second plurality of frontside gate vias comprises forming an entirety of the frontside gate vias at locations corresponding to fourth and/or fifth tracks of fourth through sixth lowermost frontside metal layer tracks extending in the second direction, the fourth through sixth tracks being aligned in order between the second and third locations and being an entirety of lowermost frontside metal layer tracks aligned between the second and third locations, and
the forming the second plurality of frontside S/D vias comprises forming an entirety of the frontside S/D vias at locations corresponding to the fifth and/or sixth tracks.

20. The method of claim 16, wherein
the constructing the first plurality of transistors comprises constructing complementary field-effect transistors (CFETs).
